(19) United States
(12) Patent Application Publication
(10) Pub. No.: US 2026/0123124 A1
(43) Pub. Date: Apr. 30, 2026

(54) MICRO-LIGHT EMITTING DIODE CHIP AND FORMING METHOD THEREOF, AND AUTOMOBILE LAMP

(71) Applicant: JADE BIRD DISPLAY (SHANGHAI) LIMITED, Shanghai (CN)

(72) Inventors: Hao WANG, Shanghai (CN); Feng FENG, Shanghai (CN)

(73) Assignee: JADE BIRD DISPLAY (SHANGHAI) LIMITED, Shanghai (CN)

(21) Appl. No.: 19/365,102

(22) Filed: Oct. 21, 2025

(30) Foreign Application Priority Data
Oct. 24, 2024 (CN) 202411498572.7

(51) Int. Cl. H10H 20/857; H01L 25/16; H10H 20/01; H10H 20/812; H10H 20/814; H10H 20/855

(52) U.S. Cl. CPC H10H 20/857; H10H 20/017; H10H 20/032; H10H 20/0364; H10H 20/812; H10H 20/814; H10H 20/855; H10W 90/00

(57) ABSTRACT

A Micro-Light Emitting Diode (Micro LED) chip and a forming method thereof, and an automobile lamp are provided. The Micro LED chip includes: a first epitaxial layer having a first side and a second side opposite to each other; a plurality of multi-quantum well layers disposed on the first side and in contact with the first epitaxial layer; a plurality of second epitaxial layers disposed on the first side, and each of the plurality of multi-quantum well layers is disposed between the first epitaxial layer and one corresponding second epitaxial layer; and a plurality of conductive mirror layers disposed on the first side, and each of the plurality of conductive mirror layers is electrically connected to one corresponding second epitaxial layer, and surrounds a non-light-emitting side of one corresponding multi-quantum well layer. Photoelectric conversion efficiency of the Micro LED chip is improved, and optical crosstalk is reduced.

### CROSS-REFERENCE TO RELATED APPLICATIONS

The present application claims priority to Chinese patent application No. 202411498572.7, filed on Oct. 24, 2024, and the entire disclosure of which is incorporated herein by reference.

### FIELD

The present disclosure relates to the field of micro-display technology, and particularly to a micro-light emitting diode chip and a forming method thereof, and an automobile lamp.

### BACKGROUND

Inorganic micro-pixel light-emitting diodes are also known as Micro-Light Emitting Diodes (Micro LED or μ-LED). Micro LED technology is plane display technology, where micron-sized LEDs are used as pixel elements and assembled on a CMOS backplane at a micron-sized period to generate a high-pixel density LED. An LED structure design is filmed, miniaturized, and arrayed, with a size of only a few microns to tens of microns, and a large number of Micro LED chips are transferred to a TFT or CMOS backplane. Micro LED display has various excellent characteristics such as high luminous efficiency, high brightness, short response time, and good reliability, and are praised by the industry as a next generation of display technology and an ultimate form of display.

### SUMMARY

Embodiments of the present disclosure provide a Micro LED chip and a forming method thereof, and an automobile lamp, to improve photoelectric conversion efficiency of the Micro LED chip and reduce optical crosstalk.

In an embodiment, a Micro LED chip is provided, including: a first epitaxial layer, and the first epitaxial layer has first doping ions therein, and has a first side and a second side opposite to each other; a plurality of multi-quantum well layers disposed on the first side and in contact with the first epitaxial layer; a plurality of second epitaxial layers disposed on the first side, and the plurality of second epitaxial layers have second doping ions therein, the second doping ions and the first doping ions are of different electrical types, and each of the plurality of multi-quantum well layers is disposed between the first epitaxial layer and one corresponding second epitaxial layer among the plurality of second epitaxial layers; and a plurality of conductive mirror layers disposed on the first side, and each of the plurality of conductive mirror layers is electrically connected to one corresponding second epitaxial layer among the plurality of second epitaxial layers, and surrounds a non-light-emitting side of one corresponding multi-quantum well layer among the plurality of multi-quantum well layers.

In some embodiments, the Micro LED chip further includes a plurality of micro-lenses disposed on the second side, and a light-emitting side of each of the plurality of multi-quantum well layers faces one corresponding micro-lens among the plurality of micro-lenses, and a projection area of each of the plurality of multi-quantum well layers toward the corresponding second epitaxial layer is disposed within a projection area range of the corresponding micro-lens toward the corresponding second epitaxial layer.

In some embodiments, the Micro LED chip further includes a plurality of fluorescent layers disposed on the second side, and each of the plurality of fluorescent layers is disposed between one corresponding multi-quantum well layer among the plurality of multi-quantum well layers and one corresponding micro-lens among the plurality of micro-lenses, and the plurality of fluorescent layers are configured to adjust a color of light emitted by the plurality of multi-quantum well layers toward the micro-lenses.

In some embodiments, the plurality of fluorescent layers excite light of a first wavelength, and the light of the first wavelength is displayed as a first color light; the plurality of multi-quantum well layers excite light of a second wavelength, and the light of the second wavelength is displayed as a second color light; the first wavelength is different from the second wavelength; and the first color light and the second color light are mixed into a third color light.

In some embodiments, the first color light is yellow light, the second color light is blue light, and the third color light is white light.

In some embodiments, the Micro LED chip further includes a dam structure disposed on the second side, and the dam structure includes a plurality of first through holes each of which exposes a light emission path of one corresponding multi-quantum well layer among the plurality of multi-quantum well layers, and each of the plurality of fluorescent layers is filled in one corresponding first through hole among the plurality of first through holes.

In some embodiments, the Micro LED chip further includes a first conductive structure disposed on the second side, and the first conductive structure is electrically connected to the first epitaxial layer, and disposed between the dam structure and the first epitaxial layer, the first conductive structure includes a plurality of second through holes, and each of the plurality of first through holes exposes one corresponding second through hole among the plurality of second through holes.

In some embodiments, each of the plurality of fluorescent layers is also filled in the corresponding second through hole.

In some embodiments, the Micro LED chip further includes a plurality of first ohmic contact layers disposed on the first side, and each of the plurality of first ohmic contact layers is disposed between one corresponding conductive mirror layer among the plurality of conductive mirror layers and one corresponding second epitaxial layer among the plurality of second epitaxial layers.

In some embodiments, a material of the plurality of first ohmic contact layers includes a transparent conductive material.

In some embodiments, the transparent conductive material includes: a transparent metal material, indium tin oxide or fluorine-doped SnO₂.

In some embodiments, a material of the dam structure includes a metal material or a silicone material, and the metal material includes: aluminum, silver, titanium or platinum.

In some embodiments, the Micro LED chip further includes a second ohmic contact layer disposed on the second side, and the second ohmic contact layer is disposed between the first conductive structure and the first epitaxial layer.

In some embodiments, a material of the second ohmic contact layer includes a transparent conductive material.

In some embodiments, the transparent conductive material includes: a transparent metal material, indium tin oxide or fluorine-doped SnO₂.

In some embodiments, a material of the conductive mirror layer includes a metal material, and the metal material includes: nickel, silver, titanium, platinum, gold or aluminum.

In some embodiments, the Micro LED chip further includes: a plurality of first conductive plugs disposed on the first side, and each of the plurality of first conductive plugs is electrically connected to one corresponding second epitaxial layer among the plurality of second epitaxial layers; and a driving backplane including a driving circuit layer, and the plurality of first conductive plugs are electrically connected to the driving circuit layer.

In some embodiments, the driving backplane further includes a plurality of driving backplane conductive plugs electrically connected to the driving circuit layer, and the plurality of first conductive plugs are electrically connected to the driving circuit layer respectively through the plurality of driving backplane conductive plugs.

In some embodiments, the Micro LED chip further includes a bonding layer disposed between the driving backplane and the plurality of first conductive plugs, and the bonding layer includes a plurality of second conductive plugs and a plurality of metal plates, each of the plurality of metal plates is electrically connected to several of the plurality of driving backplane conductive plugs, each of the plurality of second conductive plugs is electrically connected to one corresponding metal plate among the plurality of metal plates, and each of the plurality of first conductive plugs is electrically connected to one corresponding second conductive plug among the plurality of second conductive plugs.

In some embodiments, the driving backplane further includes a plurality of functional conductive plugs electrically connected to the driving circuit layer; and the bonding layer further includes a plurality of third conductive plugs each of which is electrically connected to one corresponding functional conductive plug among the plurality of functional conductive plugs.

In some embodiments, the Micro LED chip further includes: a plurality of fourth conductive plugs disposed on the first side, and each of the plurality of fourth conductive plugs is electrically connected to one corresponding third conductive plug among the plurality of third conductive plugs; and a plurality of second conductive structures disposed on the second side, and each of the plurality of second conductive structures is electrically connected to one corresponding fourth conductive plug among the plurality of fourth conductive plugs.

In some embodiments, a material of the first epitaxial layer and the second epitaxial layers includes gallium nitride.

In an embodiment, a method for forming a Micro LED chip is provided, including: forming a first epitaxial layer, having first doping ions therein and having a first side and a second side opposite to each other; forming a plurality of multi-quantum well layers on the first side and in contact with the first epitaxial layer; forming a plurality of second epitaxial layers on the first side, and the plurality of second epitaxial layers have second doping ions therein, the second doping ions and the first doping ions are of different electrical types, and each of the plurality of multi-quantum well layers is disposed between the first epitaxial layer and one corresponding second epitaxial layer among the plurality of second epitaxial layers; and forming a plurality of conductive mirror layers on the first side, and each of the plurality of conductive mirror layers is electrically connected to one corresponding second epitaxial layer among the plurality of second epitaxial layers, and surrounds a non-light-emitting side of one corresponding multi-quantum well layer among the plurality of multi-quantum well layers.

In some embodiments, prior to said forming the plurality of conductive mirror layers, the method further includes: forming a plurality of first ohmic contact layers on the first side, and each of the plurality of first ohmic contact layers is disposed between one corresponding conductive mirror layer among the plurality of conductive mirror layers and the corresponding second epitaxial layer.

In some embodiments, said forming the first epitaxial layer, the plurality of first ohmic contact layers, the plurality of second epitaxial layers and the plurality of multi-quantum well layers includes: providing a temporary substrate; forming a first epitaxial material layer on the temporary substrate; forming a multi-quantum well material layer on the first epitaxial material layer; forming a second epitaxial material layer on the multi-quantum well material layer; forming a first ohmic contact material layer on the second epitaxial material layer; and performing patterned etching on the first ohmic contact material layer, the second epitaxial material layer, the multi-quantum well material layer and the first epitaxial material layer to form the plurality of first ohmic contact layers, the plurality of second epitaxial layers, the plurality of multi-quantum well layers and the first epitaxial layer.

In some embodiments, said forming the plurality of conductive mirror layers includes: forming a third photoresist structure on the first side; forming a mirror material layer on the first side, and the mirror material layer covers the third photoresist structure; and removing the third photoresist structure and the mirror material layer on the third photoresist structure to form the plurality of conductive mirror layers.

In some embodiments, following said forming the plurality of conductive mirror layers, the method further includes: forming a plurality of first conductive plugs on the first side, and each of the plurality of first conductive plugs is electrically connected to one corresponding second epitaxial layer among the plurality of second epitaxial layers; and providing a driving backplane including a driving circuit layer, and the plurality of first conductive plugs are electrically connected to the driving circuit layer.

In some embodiments, the driving backplane further includes a plurality of driving backplane conductive plugs electrically connected to the driving circuit layer, and the plurality of first conductive plugs are electrically connected to the driving circuit layer respectively through the plurality of driving backplane conductive plugs.

In some embodiments, following said providing the driving backplane, the method further includes: forming a bonding layer on the driving backplane, and the bonding layer includes a plurality of second conductive plugs and a plurality of metal plates, each of the plurality of metal plates is electrically connected to several of the plurality of driving backplane conductive plugs, and each of the plurality of second conductive plugs is electrically connected to one corresponding metal plate among the plurality of metal plates; and bonding each of the plurality of first conductive plugs to one corresponding second conductive plug among the plurality of second conductive plugs.

In some embodiments, the driving backplane further includes a plurality of functional conductive plugs electrically connected to the driving circuit layer; and the bonding layer further includes a plurality of third conductive plugs each of which is electrically connected to one corresponding functional conductive plug among the plurality of functional conductive plugs.

In some embodiments, the method further includes: forming a plurality of fourth conductive plugs on the first side, and each of the plurality of fourth conductive plugs is electrically connected to one corresponding third conductive plug among the plurality of third conductive plugs; and forming a plurality of second conductive structures disposed on the second side, and each of the plurality of second conductive structures is electrically connected to one corresponding fourth conductive plug among the plurality of fourth conductive plugs.

In some embodiments, following said forming the conductive mirror layer, the method further includes: forming a plurality of micro-lenses on the second side, and a light-emitting side of each of the plurality of multi-quantum well layers faces one corresponding micro-lens among the plurality of micro-lenses, and a projection area of each of the plurality of multi-quantum well layers toward the corresponding second epitaxial layer is disposed within a projection area range of the corresponding micro-lens toward the corresponding second epitaxial layer.

In some embodiments, prior to said forming the plurality of micro-lenses, the method further includes: forming a plurality of fluorescent layers on the second side, and each of the plurality of fluorescent layers is disposed between one corresponding multi-quantum well layer among the plurality of multi-quantum well layers and one corresponding micro-lens among the plurality of micro-lenses, and the plurality of fluorescent layers are configured to adjust a color of light emitted by the plurality of multi-quantum well layers toward the micro-lenses.

In some embodiments, prior to said forming the plurality of fluorescent layers, the method further includes: forming a dam structure on the second side, and the dam structure includes a plurality of first through holes each of which exposes a light emission path of one corresponding multi-quantum well layer among the plurality of multi-quantum well layers, and each of the plurality of fluorescent layers is filled in one corresponding first through hole among the plurality of first through holes.

In some embodiments, said forming the dam structure includes: forming a plurality of first photoresist structures on the second side, with a first gap between adjacent first photoresist structures; forming the dam structure in the first gap; and removing the plurality of first photoresist structures after forming the dam structure, to make the dam structure have the plurality of first through holes.

In some embodiments, prior to said forming the dam structure, the method further includes: forming a first conductive structure on the second side, and the first conductive structure is electrically connected to the first epitaxial layer, and disposed between the dam structure and the first epitaxial layer, the first conductive structure includes a plurality of second through holes, and each of the plurality of first through holes exposes one corresponding second through hole among the plurality of second through holes.

In some embodiments, said forming the first conductive structure includes: forming a plurality of second photoresist structures on the second side, with a second gap between adjacent second photoresist structures; forming the first conductive structure in the second gap; removing the plurality of second photoresist structures after forming the first conductive structure, to make the first conductive structure have the plurality of second through holes.

In some embodiments, each of the plurality of fluorescent layers is also filled in the corresponding second through hole.

In some embodiments, prior to said forming the first conductive structure, the method further includes: forming a second ohmic contact layer on the second side, and the second ohmic contact layer is disposed between the first conductive structure and the first epitaxial layer.

In an embodiment, an automobile lamp is provided, including the Micro LED chip provided in any one of the above embodiments.

Compared with the existing techniques, embodiments of the present disclosure have following advantages.

In the Micro LED chip provided by the embodiments of the present disclosure, a plurality of conductive mirror layers are provided on the second side, each conductive mirror layer is electrically connected to the corresponding second epitaxial layer, and each conductive mirror layer surrounds the non-light-emitting side of the corresponding multi-quantum well layer. By providing the plurality of conductive mirror layers, the conductive mirror layers cannot only meet electrical connection requirements of the Micro LED chip, but also block and reflect light emitted by the multi-quantum well layers toward the non-light-emitting side, thereby improving photoelectric conversion efficiency of the Micro LED chip and reducing optical crosstalk.

Further, the Micro LED chip further includes a plurality of fluorescent layers disposed on the second side. Each fluorescent layer is disposed between the corresponding multi-quantum well layer and the corresponding micro-lens, and is used to adjust the color of the light emitted by the multi-quantum well layer toward the micro-lens. By providing the fluorescent layers, the color of the light emitted by the multi-quantum well layers toward the micro-lenses is adjusted to meet requirement of different usage scenarios.

Further, the Micro LED chip further includes a plurality of first ohmic contact layers disposed on the first side. Each first ohmic contact layer is disposed between the corresponding conductive mirror layer and the corresponding second epitaxial layer. The first ohmic contact layers may effectively reduce contact resistance between the conductive mirror layers and the second epitaxial layers.

Further, the Micro LED chip further includes a second ohmic contact layer disposed on the second side. The second ohmic contact layer is disposed between the first conductive structure and the first epitaxial layer. The second ohmic contact layer may effectively reduce contact resistance between the first conductive structure and the first epitaxial layer.

Further, the Micro LED chip further includes a bonding layer disposed between the driving backplane and the plurality of first conductive plugs. The bonding layer includes a plurality of second conductive plugs and a plurality of metal plates. Each metal plate is electrically connected to several driving backplane conductive plugs, each second conductive plug is electrically connected to the corresponding metal plate, and each first conductive plug is electrically connected to the corresponding second conductive plug. Electrically connecting the several driving backplane conductive plugs through the metal plate can effectively reduce power supply pressure of a single driving backplane conductive plug, to provide a relatively large current for each first conductive plug.

In the method for forming the Micro LED chip provided by the embodiments of the present disclosure, a plurality of conductive mirror layers are formed on the second side, and each conductive mirror layer is electrically connected to the corresponding second epitaxial layer, and surrounds the non-light-emitting side of the corresponding multi-quantum well layer. By providing the plurality of conductive mirror layers, the conductive mirror layers cannot only meet the electrical connection requirements of the Micro LED chip, but also block and reflect the light emitted by the multi-quantum well layers toward the non-light-emitting side, thereby improving the photoelectric conversion efficiency of the Micro LED chip and reducing optical crosstalk.

Further, the method further includes: forming a bonding layer on the driving backplane, where the bonding layer includes a plurality of second conductive plugs and a plurality of metal plates, each metal plate is electrically connected to several driving backplane conductive plugs, and each second conductive plug is electrically connected to the corresponding metal plate; and bonding each first conductive plug to the corresponding second conductive plug. Electrically connecting several driving backplane conductive plugs through the metal plate can effectively reduce the power supply pressure of a single driving backplane conductive plug, to provide a relatively large current for each first conductive plug.

Further, the method further includes: forming a plurality of fluorescent layers on the second side. Each fluorescent layer is disposed between the corresponding multi-quantum well layer and the corresponding micro-lens, and is used to adjust the color of the light emitted by the multi-quantum well layer toward the micro-lens. By forming the fluorescent layers, the color of the light emitted by the multi-quantum well layers toward the micro-lenses is adjusted to meet the requirements of different usage scenarios.

Further, the method further includes: forming a plurality of first ohmic contact layers on the first side. Each first ohmic contact layer is disposed between the corresponding conductive mirror layer and the corresponding second epitaxial layer. The first ohmic contact layers may effectively reduce contact resistance between the conductive mirror layers and the second epitaxial layers.

Further, the method further includes: forming a second ohmic contact layer on the second side. The second ohmic contact layer is disposed between the first conductive structure and the first epitaxial layer. The second ohmic contact layer may effectively reduce contact resistance between the first conductive structure and the first epitaxial layer.

In the automobile lamp provided by the embodiments of the present disclosure, a traditional automobile lamp is replaced with a Micro LED chip, which may effectively improve a resolution and luminous flux of the automobile lamp.

### BRIEF DESCRIPTION OF THE DRAWINGS

FIG. 1 to FIG. 14 are schematic structural diagrams of steps of a method for forming a Micro LED chip according to an embodiment of the present disclosure.

### DETAILED DESCRIPTION

There are still many problems with the existing Micro LED chips, which are described in detail below.

Although the existing Micro LED chips have many advantages, they also face technical challenges currently, such as low photoelectric conversion efficiency and optical crosstalk.

On this basis, embodiments of the present disclosure provide a Micro LED chip and a forming method thereof, and an automobile lamp. A plurality of conductive mirror layers are provided on a second side, each conductive mirror layer is electrically connected to a corresponding second epitaxial layer, and each conductive mirror layer surrounds a non-light-emitting side of a corresponding multi-quantum well layer. By providing the plurality of conductive mirror layers, the conductive mirror layers cannot only meet electrical connection requirements of the Micro LED chip, but also block and reflect light emitted by the multi-quantum well layers toward the non-light-emitting side, thereby improving photoelectric conversion efficiency of the Micro LED chip and reducing optical crosstalk.

In order to make the embodiments of the present disclosure more understandable, the embodiments of the present disclosure are clearly and completely described below in conjunction with drawings in the embodiments of the present disclosure. Obviously, the described embodiments are only part of the embodiments of the present disclosure, but not all of the embodiments.

In the description of the present disclosure, it should be understood that positions or positional relationships indicated by the terms “upper”, “lower”, “top surface”, “bottom surface” and the like are positions or positional relationships shown in the accompanying drawings, and are only for facilitating describing the present disclosure and simplifying the description, rather than indicating or implying that the positions or elements referred to must have a specific orientation, and be constructed and operate in a specific orientation, which therefore cannot be understood as limitations of the present disclosure. In addition, the terms “first” and “second” are only used to distinguish an entity or operation from another entity or operation, and do not require or imply any actual relationship, order or relative importance between these entities or operations.

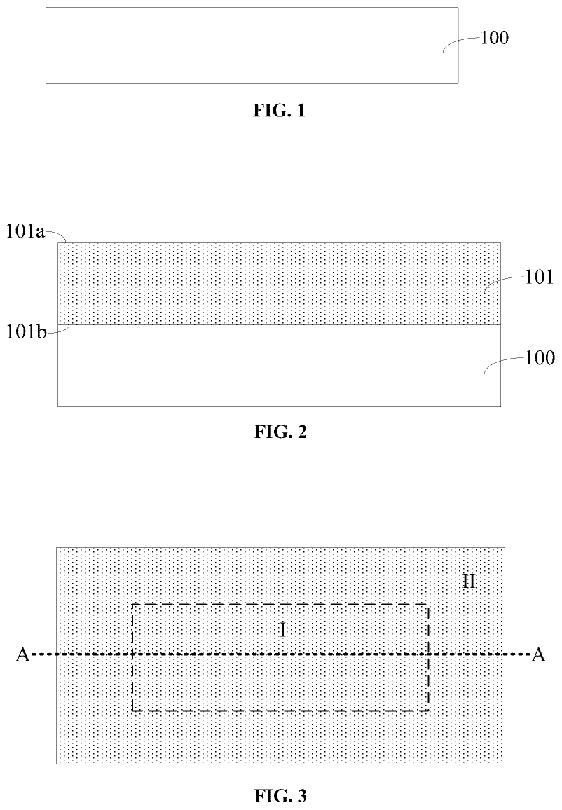

FIG. 1 to FIG. 14 are schematic structural diagrams of steps of a method for forming a Micro LED chip according to an embodiment of the present disclosure.

A first epitaxial layer, a plurality of multi-quantum well layers and a plurality of second epitaxial layers are formed. A specific forming process is shown in FIG. 1 to FIG. 7.

Referring to FIG. 1, a temporary substrate 100 is provided.

In the embodiment, a flip-chip manufacturing process is adopted for forming the Micro LED chip. The temporary substrate 100 may be an epitaxial substrate layer, and used as a temporary supporting structure in the flip-chip manufacturing process of the Micro LED chip. After an actual device structure of the Micro LED chip is completed subsequently, the temporary substrate 100 needs to be removed.

Referring to FIG. 2 and FIG. 3, FIG. 2 is a schematic cross-sectional view along line A-A in FIG. 3. A first epitaxial material layer 101 is formed on the temporary substrate 100.

In the embodiment, the first epitaxial material layer 101 is doped with first doping ions of N-type.

In the embodiment, a material of the first epitaxial material layer 101 is gallium nitride.

In the embodiment, the first epitaxial material layer 101 has a first side 101a and a second side 101b opposite to each other, and the temporary substrate 100 is disposed on the second side 101b.

In the embodiment, the first epitaxial material layer 101 includes a display area I, and a non-display area II surrounding the display area I. In subsequent processes, pixels formed based on the display area I have a light-emitting function, while pixels formed based on the non-display area II do not have the light-emitting function. The function of the pixels formed based on the non-display area II is to make structural environment areas of the display area I and the non-display area II tend to be consistent, thereby reducing a film peeling problem caused by stress difference during subsequent coating, and eliminating a step height difference between the display area I and the non-display area II, which is beneficial to a subsequent bonding process.

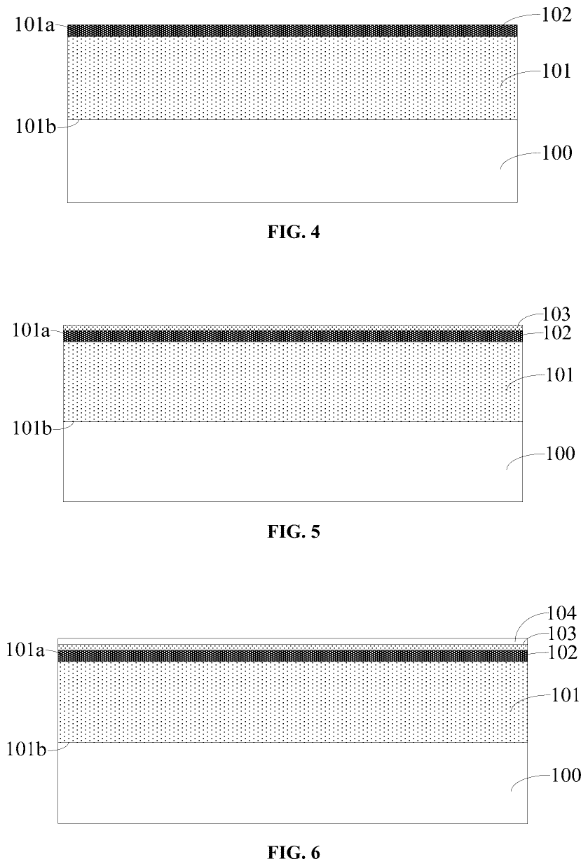

Referring to FIG. 4 which has the same direction of view as FIG. 2, a multi-quantum well material layer 102 is formed on the first epitaxial material layer 101.

In the embodiment, the multi-quantum well material layer 102 is disposed on the first side 101a.

Referring to FIG. 5, a second epitaxial material layer 103 is formed on the multi-quantum well material layer 102.

In the embodiment, the second epitaxial material layer 103 is doped with second doping ions of P-type which is an electrical type different from that of the first doping ions.

In the embodiment, the second epitaxial material layer 103 is disposed on the first side 101a, and the multi-quantum well material layer 102 is disposed between the first epitaxial material layer 101 and the second epitaxial material layer 103.

In the embodiment, a material of the second epitaxial material layer 103 is gallium nitride.

Referring to FIG. 6, a first ohmic contact material layer 104 is formed on the second epitaxial material layer 103.

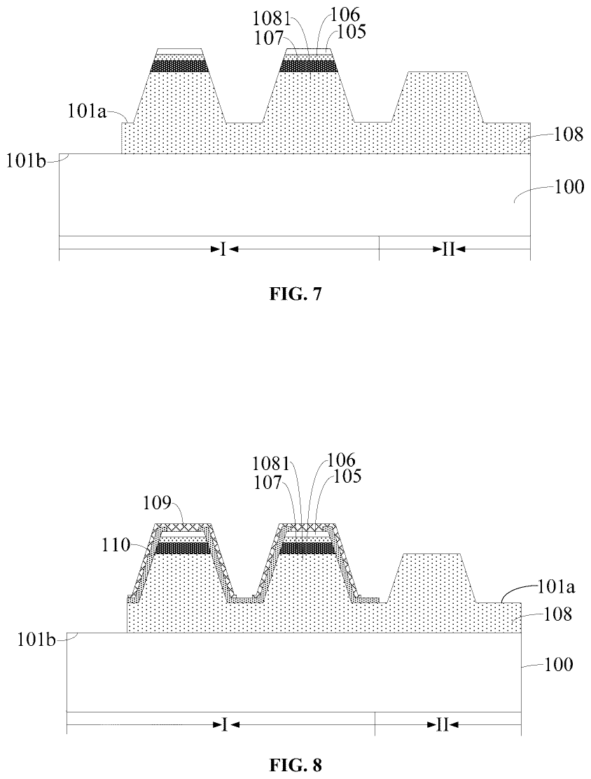

Referring to FIG. 7, the first ohmic contact material layer 104, the second epitaxial material layer 103, the multi-quantum well material layer 102 and the first epitaxial material layer 101 are subjected to a patterned etching process to form a plurality of first ohmic contact layers 105, a plurality of second epitaxial layers 106, a plurality of multi-quantum well layers 107 and a first epitaxial layer 108.

In the embodiment, the multi-quantum well layers 107, the second epitaxial layers 106 and the first ohmic contact layers 105 are all disposed on the first side 101a. Each multi-quantum well layer 107 is disposed between the first epitaxial layer 108 and the corresponding second epitaxial layer 106, and each second epitaxial layer 106 is disposed between the corresponding multi-quantum well layer 107 and the corresponding first ohmic contact layer 105. The first epitaxial layer 108 and the second epitaxial layers 106 serve as the positive electrode and the negative electrode of the Micro LED chip, respectively.

In the embodiment, after the first epitaxial material layer 101 is subjected to the patterned etching process, the formed first epitaxial layer 108 has a plurality of protrusions 1081.

In the embodiment, after the first ohmic contact material layer 104, the second epitaxial material layer 103, the multi-quantum well material layer 102 and the first epitaxial material layer 101 are subjected to a patterned etching process, a plurality of mesas are formed. Each mesa includes: the protrusion 1081 of the first epitaxial layer 108, the multi-quantum well layer 107 on the protrusion 1081, the second epitaxial layer 106 on the multi-quantum well layer 107, and the first ohmic contact layer 105 on the second epitaxial layer 106.

In the embodiment, a sidewall of each mesa is an inclined surface, that is, a diameter of the mesa gradually decreases from a bottom surface of the protrusion 1081 to a top surface of the first ohmic contact layer 105. By setting the sidewall of the mesa as the inclined surface, a conductive mirror layer formed based on the mesas can reflect light toward a direction of micro-lens as much as possible, thereby further improving photoelectric conversion efficiency.

It should be noted that the mesas formed after the patterned etching process are evenly distributed in the display area I and the non-display area II, where a number of mesas in the display area I exceeds 2 million, that is, a resolution of the Micro LED chip exceeds 2 million. As pixels in the non-display area II do not have a light-emitting function, the mesa in the non-display area II only has the protrusion 1081, and one or more of the multi-quantum well layer 107, the second epitaxial layer 106 and the first ohmic contact layer 105 may not be formed, or may be formed. Each pixel on the non-display area II will not light up without a corresponding driving circuit and plug to power it at a driving backplane position provided subsequently.

It should be noted that FIG. 7 merely illustrates a portion of the mesas in the display area I and the non-display area II.

It should be noted that, in the embodiment, the first ohmic contact layer 105 cannot block light emitted by the multi-quantum well layer 107 toward the subsequently formed conductive mirror layers, which may affect light reflection by the conductive mirror layers. Therefore, the first ohmic contact layer 105 needs to include a transparent conductive material, specifically a transparent metal material, indium tin oxide or fluorine-doped SnO₂.

It should be noted that the multi-quantum well layer 107 may emit light of different colors mainly because of having specific physical properties which enable recombination of electrons and holes to occur at different energy levels, thereby emitting light of different wavelengths.

A technical principle of the multi-quantum well layer 107 involves concepts of quantum physics. Energy states of electrons and holes are confined to a specific area, and this confinement leads to discreteness of energy levels. When the electrons jump from a high energy level to a low energy level, photons are released, and energy of the photons depends on an energy difference between the energy levels. A structure of the multi-quantum well layer 107 can accurately control positions of the energy levels, thus the wavelength of the emitted light, i.e., the color of the light, can be accurately controlled.

Specifically, the multi-quantum well layer 107 is composed of two or more different semiconductor material films alternately stacked, and thickness and materials of these films determine characteristics of the energy level. By adjusting the thickness and materials of these films, a recombination process of the electrons and holes can be accurately controlled, and then the wavelength of the emitted light can be controlled to achieve the emission of light of different colors. For example, by adjusting structural parameters of the InGaAs/InGaAsP multi-quantum well layer 107, laser output with wavelengths of 1.3 microns and 1.5 microns can be obtained. Light with these specific wavelengths corresponds to different colors required in communication and display technology.

In addition, the application of the multi-quantum well layer 107 is not limited to emitting light of a single color. By designing and adjusting the combination and structure of the materials, multiple colors of output can be achieved, which is of great significance to fields such as display technology and optical communication. For example, quantum dot technology can achieve full-color display by controlling a size and materials of quantum dots, which has been widely used in modern display technology.

Referring to FIG. 8, a plurality of conductive mirror layers 109 are formed on the first side 101a, and each conductive mirror layer 109 is electrically connected to the corresponding second epitaxial layer 106, and surrounds a non-light-emitting side of the corresponding multi-quantum well layer 107.

By providing the plurality of conductive mirror layers 109, the conductive mirror layers cannot only meet electrical connection requirements of the Micro LED chip, but also block and reflect light emitted by the multi-quantum well layers toward the non-light-emitting side, thereby improving photoelectric conversion efficiency of the Micro LED chip and reducing optical crosstalk.

It should be noted that in the embodiment, as the light emitted by the multi-quantum well layers 107 ultimately needs to be collected and emitted through subsequently formed micro-lenses, a side where the micro-lenses are disposed is a light-emitting side of the multi-quantum well layers 107, and other sides are all non-light-emitting sides of the multi-quantum well layers.

In the embodiment, each first ohmic contact layer 105 is disposed between the corresponding conductive mirror layer 109 and the corresponding second epitaxial layer 106. By providing the first ohmic contact layers 105, contact resistance between the conductive mirror layers 109 and the second epitaxial layer 106s can be effectively reduced.

In the embodiment, forming the plurality of conductive mirror layers 109 includes: forming a third photoresist structure (not shown) on the first side 101a; forming a mirror material layer (not shown) on the first side 101a, where the mirror material layer covers the third photoresist structure; and removing the third photoresist structure and the mirror material layer on the third photoresist structure to form the plurality of conductive mirror layers 109.

It should be noted that the third photoresist structure covers a position where the conductive mirror layer 109 does not need to be formed.

It should be noted that in the embodiment, as the display area I is used to form pixels with light-emitting function, the conductive mirror layers 109 are merely formed on the mesas in the display area I, but not formed on the mesas in the non-display area II.

In the embodiment, the conductive mirror layers 109 are made of a metal material, such as nickel, silver, titanium, platinum, gold or aluminum.

Still referring to FIG. 8, in the embodiment, prior to forming the conductive mirror layers 109, passivation layers 110 are formed on the first side 101a. The passivation layers 110 cover a surface of several mesas, and expose the first ohmic contact layers 105 of the mesas in the display area I to ensure that the conductive mirrors layers 109 can be electrically connected to the corresponding first ohmic contact layers 105.

In the embodiment, the passivation layers 110 mainly realize electrical isolation. The first passivation material layers may be an Aluminum Oxide (Al₂O₃) film formed by an atomic layer deposition process with good step coverage.

Still referring to FIG. 8, in the embodiment, specifically, the passivation layer 110 includes three portions (not shown). The first portion covers a surface of several mesas, is disposed between the first ohmic contact layer 105 and the conductive mirror layer 109, and exposes a portion of the first ohmic contact layer 105. The exposed portion of the first ohmic contact layer 105 contacts the conductive mirror layer 109. The second portion covers a side surface of several mesas, is disposed between the side surface of the mesas and the conductive mirror layer 109. The third portion covers a surface of the first epitaxial layer 108 in a gap between adjacent mesas. The first portion, the second portion, and the third portion of the passivation layer 110 are connected to each other.

In some variant embodiments, the passivation layer 110 may include merely the second and third portions described above, and the top of the second portion of the passivation layer 110 is flush with the top of the first ohmic contact layer 105, or the top of the second portion is slightly lower than a top surface of the second epitaxial layer 106.

It should be noted that in the embodiment, as the pixels in the non-display area II do not have the light-emitting function, the mesas in the non-display area II may not include the conductive mirror layer 109 (i.e., it is pre-covered by the third photoresist structure), and the passivation layer 110 may not be retained.

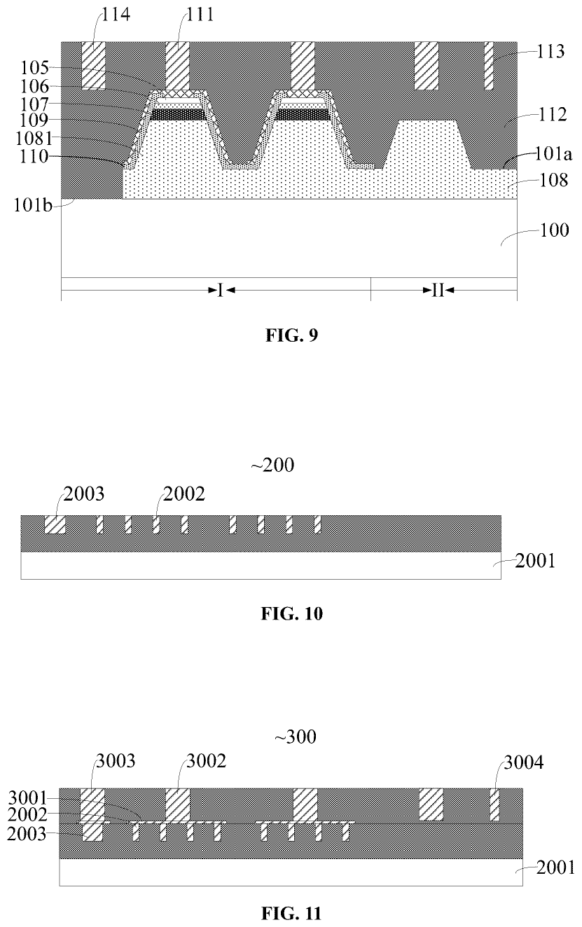

Referring to FIG. 9, after the conductive mirror layer 109 is formed, a plurality of first conductive plugs 111 are formed on the first side 101a, and each first conductive plug 111 is electrically connected to the corresponding second epitaxial layer 106.

In the embodiment, forming the first conductive plugs 111 includes: forming a dielectric layer 112 on the first side 101a, the dielectric layer 112 covering the plurality of mesas; forming a plurality of plug through holes (not shown) in the dielectric layer 112; and forming the plurality of first conductive plugs 111 in the plurality of plug through holes.

It should be noted that, in the embodiment, the mesas in the display area I are electrically connected to the corresponding first conductive plugs 111, while the mesas in the non-display area II are not electrically connected to the corresponding first conductive plugs 111.

In the embodiment, while forming the first conductive plugs 111, a first alignment mark 113 and a plurality of fourth conductive plugs 114 are also formed in the dielectric layer 112. The first alignment mark 113 is used to align itself with a second alignment mark formed in a bonding layer in a subsequent bonding process, thereby reducing an offset caused by bonding. The fourth conductive plug 114 is used to introduce a functional pin of a subsequent driving backplane to the first side 101a.

Referring to FIG. 10, a driving backplane 200 is provided.

In the embodiment, the driving backplane 200 includes: a driving circuit layer 2001; a plurality of driving backplane conductive plugs 2002, which are electrically connected to the driving circuit layer 2001; and a plurality of functional conductive plugs 2003, which are electrically connected to the driving circuit layer 2001.

In the embodiment, the driving backplane 200 is an IC board or a TET board.

Referring to FIG. 11, a bonding layer 300 is formed on the driving backplane 200. The bonding layer 300 includes: a plurality of metal plates 3001, each of which is electrically connected to several of the plurality of driving backplane conductive plugs 2002; a plurality of second conductive plugs 3002, each of which is electrically connected to the corresponding metal plate 3001; and a plurality of third conductive plugs 3003, each of which is electrically connected to the corresponding functional conductive plug 2003.

By electrically connecting the several driving backplane conductive plugs 2002 via the metal plate 3001, a power supply pressure of a single driving backplane conductive plug 2002 is effectively reduced, to provide a relatively large current for each first conductive plug 111 in the display area I.

It should be noted that, in the embodiment, the plurality of functional conductive plugs 2003 are used as transmission media to enable the driving backplane 200 to provide voltage or data input and output to the Micro LED chip.

Still referring to FIG. 11, in the embodiment, the bonding layer further includes a second alignment mark 3004.

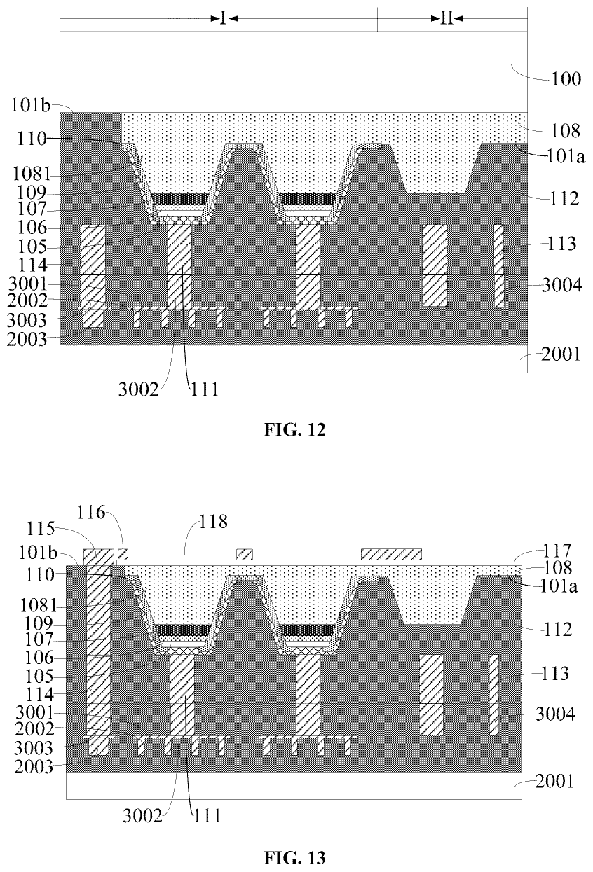

Referring to FIG. 12, each first conductive plug 111 is bonded to the corresponding second conductive plug 3002.

In the embodiment, when each first conductive plug 111 is bonded to the corresponding second conductive plug 3002, each third conductive plug 3003 is also bonded to the corresponding fourth conductive plug 114, and the first alignment mark 113 is aligned with the second alignment mark 3004.

It should be noted that in the embodiment, the second conductive plugs 3002 are formed in the bonding layer 300 and are bonded to the first conductive plugs 111 in the non-display area II, which makes bonding situations of the display area I and the non-display area II as consistent as possible to improve bonding quality.

Referring to FIG. 13, a plurality of second conductive structures 115 are formed on the second side 101b, and each second conductive structure 115 is electrically connected to the corresponding fourth conductive plug 114.

It should be noted that in the embodiment, before the second conductive structures 115 are formed, the temporary substrate 100 needs to be removed, and the first epitaxial layer 108 needs to be thinned accordingly.

In the embodiment, when the second conductive structures 115 are formed, a first conductive structure 116 is further formed on the second side 10b, and the first conductive structure 116 is electrically connected to the first epitaxial layer 108.

Still referring to FIG. 13, in the embodiment, before the first conductive structure 116 is formed, a second ohmic contact layer 117 is formed on the second side 101b, and the second ohmic contact layer 117 is disposed between the first conductive structure 116 and the first epitaxial layer 108. The second ohmic contact layer 117 may effectively reduce contact resistance between the first conductive structure 116 and the first epitaxial layer 108.

It should be noted that in the embodiment, the second ohmic contact layer 117 cannot block light emitted by the multi-quantum well layers 107 toward the subsequently formed micro-lenses, thus the second ohmic contact layer 117 also needs to be made of a transparent conductive material, such as a transparent metal material, indium tin oxide or fluorine-doped SnO₂.

Still referring to FIG. 13, in the embodiment, the fourth conductive plugs 114 do not completely penetrate the dielectric layer 112. To ensure that the second conductive structures 115 can be electrically connected to the fourth conductive plugs 114, after the second ohmic contact layer 117 is formed, corresponding opening etching is required to expose each fourth conductive plug 114, and the second conductive structures 115 can be electrically connected to the fourth conductive plugs 114 respectively.

It should be noted that the second conductive structure 115 is directly electrically connected to the corresponding fourth conductive plug 114, and neither the second conductive structure 115 nor the fourth conductive plug 114 is electrically connected to the second ohmic contact layer 117 and the first epitaxial layer 108 to avoid short circuit between the second conductive structure 115 and the first conductive structure 116.

In the embodiment, forming the first conductive structure 116 includes: forming a plurality of second photoresist structures (not shown) on the second side 101b, with a second gap between adjacent second photoresist structures; forming the first conductive structure 116 in the second gap; after forming the first conductive structure 116, removing the plurality of second photoresist structures, and the first conductive structure 116 has a plurality of second through holes 118 each of which exposes a light emission path of the corresponding multi-quantum well layer 107.

It should be noted that in the embodiment, during the formation, a position of the second conductive structures 115 is determined based on the plurality of second photoresist structures.

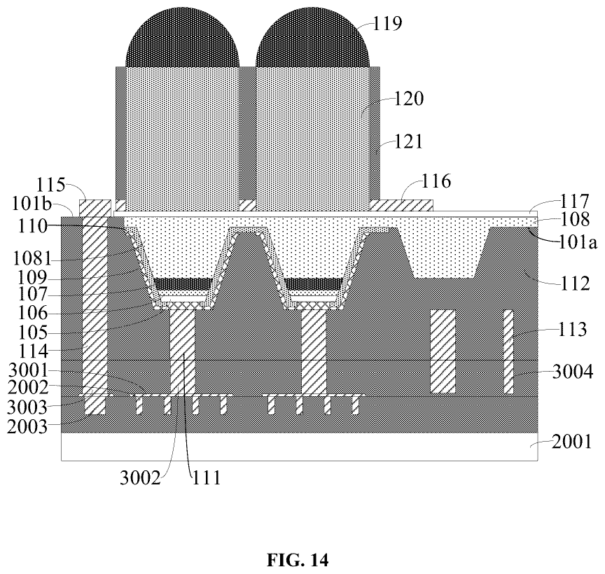

Referring to FIG. 14, a plurality of micro-lenses 119 are formed on the second side 101b, a light-emitting side of each multi-quantum well layer 107 faces the corresponding micro-lens 119, and a projection area of each multi-quantum well layer 107 toward the corresponding second epitaxial layer 106 is disposed within a projection area of the corresponding micro-lens 119 toward the corresponding second epitaxial layer 106.

In the embodiment, the micro-lenses 119 are hemispherical in shape, which may effectively improve luminous efficiency of the Micro LED chip.

In the embodiment, a material of the micro-lenses 119 is Benzocyclobutene (BCB).

Still referring to FIG. 14, in the embodiment, before the plurality of micro-lenses 119 are formed, a plurality of fluorescent layers 120 are formed on the second side 101b, each fluorescent layer 120 being disposed between the corresponding multi-quantum well layer 107 and the corresponding micro-lens 119. The fluorescent layers 120 are used to adjust a color of light emitted from the multi-quantum well layers 107 toward the micro-lenses 119. By providing the fluorescent layers 120, the color of the light emitted from the multi-quantum well layers 107 toward the micro-lenses 119 is adjusted to meet requirements of different usage scenarios.

In the embodiment, the plurality of fluorescent layers 120 excite light of a first wavelength, and the light of the first wavelength is displayed as a first color light. The plurality of multi-quantum well layers 107 excite light of a second wavelength, and the light of the second wavelength is displayed as a second color light. The first wavelength is different from the second wavelength. The first color light and the second color light are mixed into a third color light.

In a specific embodiment, the first color light is yellow light, the second color light is blue light, and the third color light is white light.

Still referring to FIG. 14, in the embodiment, before the plurality of fluorescent layers 120 are formed, a dam structure 121 is formed on the second side 101b, the dam structure 121 having a plurality of first through holes (not shown) each of which exposes a light emission path of the corresponding multi-quantum well layer 107. Each fluorescent layer 120 is filled in the corresponding first through hole.

In the embodiment, forming the dam structure 121 includes: forming a plurality of first photoresist structures (not shown) on the second side 101b, with a first gap between adjacent first photoresist structures; forming the dam structure 121 in the first gap; removing the plurality of first photoresist structures after forming the dam structure 121, to make the dam structure 121 have a plurality of first through holes.

In the embodiment, the first conductive structure 116 is disposed between the dam structure 121 and the first epitaxial layer 108. Each first through hole exposes the corresponding second through hole 118, and also exposes the light emission path of the corresponding multi-quantum well layer 107.

Still referring to FIG. 14, in the embodiment, each fluorescent layer 120 is also filled in the corresponding second through hole 118.

It should be noted that in the embodiment, the micro-lenses 119 and the fluorescent layers 120 are only manufactured on the pixels in the display area I. As the pixels in the non-display area II do not have the light-emitting function, and a subsequent electrical connection structure needs to be formed on the non-display area II, the micro-lenses 119 and the fluorescent layers 120 are not manufactured on the pixels in the non-display area II.

Accordingly, an embodiment of the present disclosure further provides a Micro LED chip. Referring to FIG. 14, the Micro LED chip includes: a first epitaxial layer 108, and the first epitaxial layer 108 has first doping ions therein, and has a first side 101a and a second side 101b opposite to each other; a plurality of multi-quantum well layers 107 disposed on the first side 101a and in contact with the first epitaxial layer 108; a plurality of second epitaxial layers 106 disposed on the first side 101a, and the plurality of second epitaxial layers 106 have second doping ions therein, the second doping ions and the first doping ions are of different electrical types, and each of the plurality of multi-quantum well layers 107 is disposed between the first epitaxial layer 108 and one corresponding second epitaxial layer 106 among the plurality of second epitaxial layers 106; and a plurality of conductive mirror layers 109 disposed on the first side 101a, and each of the plurality of conductive mirror layers 109 is electrically connected to one corresponding second epitaxial layer 106 among the plurality of second epitaxial layers 106, and surrounds a non-light-emitting side of one corresponding multi-quantum well layer 107 among the plurality of multi-quantum well layers 107.

By providing the plurality of conductive mirror layers 109, the conductive mirror layers 109 cannot only meet electrical connection requirements of the Micro LED chip, but also block and reflect light emitted by the multi-quantum well layers 107 toward the non-light-emitting side, thereby improving photoelectric conversion efficiency of the Micro LED chip and reducing optical crosstalk.

In the embodiment, the Micro LED chip further includes a plurality of micro-lenses 119 disposed on the second side 101b. A light-emitting side of each of the plurality of multi-quantum well layers 107 faces one corresponding micro-lens 119 among the plurality of micro-lenses 119, and a projection area of each of the plurality of multi-quantum well layers 107 toward the corresponding second epitaxial layer 106 is disposed within a projection area range of the corresponding micro-lens 119 toward the corresponding second epitaxial layer 106.

In the embodiment, the Micro LED chip further includes a plurality of fluorescent layers 120 disposed on the second side 101b. Each of the plurality of fluorescent layers 120 is disposed between one corresponding multi-quantum well layer 107 among the plurality of multi-quantum well layers 107 and one corresponding micro-lens 119 among the plurality of micro-lenses 119. The plurality of fluorescent layers 120 are configured to adjust a color of light emitted by the plurality of multi-quantum well layers 107 toward the micro-lenses 119. By providing the fluorescent layers 120, the color of the light emitted from the multi-quantum well layers 107 toward the micro-lenses 119 is adjusted to meet requirements of different usage scenarios.

In the embodiment, the plurality of fluorescent layers 120 excite a first color light, the plurality of multi-quantum well layers excite a second color light, and the first color light and the second color light are mixed into a third color light. Specifically, the first color light is yellow light, the second color light is blue light, and the third color light is white light.

In the embodiment, the Micro LED chip further includes a dam structure 121 disposed on the second side 101b. The dam structure 121 includes a plurality of first through holes each of which exposes a light emission path of one corresponding multi-quantum well layer 107 among the plurality of multi-quantum well layers 107, and each of the plurality of fluorescent layers 120 is filled in one corresponding first through hole among the plurality of first through holes.

In the embodiment, the Micro LED chip further includes a first conductive structure 116 disposed on the second side 101b. The first conductive structure 116 is electrically connected to the first epitaxial layer 108, and disposed between the dam structure 121 and the first epitaxial layer 108. The first conductive structure 116 includes a plurality of second through holes 118, and each of the plurality of first through holes exposes one corresponding second through hole 118 among the plurality of second through holes 118.

In the embodiment, each of the plurality of fluorescent layers 120 is also filled in the corresponding second through hole 118.

In the embodiment, the Micro LED chip further includes a plurality of first ohmic contact layers 105 disposed on the first side 101a. Each of the plurality of first ohmic contact layers 105 is disposed between one corresponding conductive mirror layer 109 among the plurality of conductive mirror layers 109 and one corresponding second epitaxial layer 106 among the plurality of second epitaxial layers 106. The first ohmic contact layers 105 may effectively reduce contact resistance between the conductive mirror layers 109 and the second epitaxial layers 106.

In the embodiment, a material of the plurality of first ohmic contact layers 105 includes a transparent conductive material, such as a transparent metal material, indium tin oxide or fluorine-doped SnO₂.

In the embodiment, a material of the dam structure 121 includes a metal material or a silicone material, and the metal material includes aluminum, silver, titanium or platinum.

In the embodiment, the Micro LED chip further includes a second ohmic contact layer 117 disposed on the second side 101b, where the second ohmic contact layer 117 is disposed between the first conductive structure 116 and the first epitaxial layer 108. The second ohmic contact layer 117 may effectively reduce contact resistance between the first conductive structure 116 and the first epitaxial layer 108.

In the embodiment, a material of the second ohmic contact layer 117 includes a transparent conductive material, such as a transparent metal material, indium tin oxide or fluorine-doped SnO₂.

In the embodiment, a material of the conductive mirror layer 109 includes a metal material, and the metal material includes nickel, silver, titanium, platinum, gold or aluminum.

In the embodiment, the Micro LED chip further includes: a plurality of first conductive plugs 111 disposed on the first side 101a, where each of the plurality of first conductive plugs 111 is electrically connected to one corresponding second epitaxial layer 106 among the plurality of second epitaxial layers 106; and a driving backplane 200 including a driving circuit layer 2001, where the plurality of first conductive plugs 111 are electrically connected to the driving circuit layer 2001.

In the embodiment, the driving backplane 200 further includes a plurality of driving backplane conductive plugs 2002 electrically connected to the driving circuit layer 2001, and the plurality of first conductive plugs 111 are electrically connected to the driving circuit layer 2001 respectively through the plurality of driving backplane conductive plugs 2002.

In the embodiment, the Micro LED chip further includes a bonding layer 300 disposed between the driving backplane 200 and the plurality of first conductive plugs 111. The bonding layer 300 includes a plurality of second conductive plugs 3002 and a plurality of metal plates 3001, each of the plurality of metal plates 3001 is electrically connected to several of the plurality of driving backplane conductive plugs 2002, each of the plurality of second conductive plugs 3002 is electrically connected to one corresponding metal plate 3001 among the plurality of metal plates 3001, and each of the plurality of first conductive plugs 111 is electrically connected to one corresponding second conductive plug 3002 among the plurality of second conductive plugs 3002. Electrically connecting the several driving backplane conductive plugs 2002 through the metal plate 3001 can effectively reduce power supply pressure of a single driving backplane conductive plug 2002, to provide a relatively large current for each first conductive plug 111.

In the embodiment, the driving backplane 200 further includes a plurality of functional conductive plugs 2003 electrically connected to the driving circuit layer 2001. The bonding layer 300 further includes a plurality of third conductive plugs 3003 each of which is electrically connected to one corresponding functional conductive plug 2003 among the plurality of functional conductive plugs 2003.

In the embodiment, the Micro LED chip further includes: a plurality of fourth conductive plugs 114 disposed on the first side 101a, where each of the plurality of fourth conductive plugs 114 is electrically connected to one corresponding third conductive plug 3003 among the plurality of third conductive plugs 3003; and a plurality of second conductive structures 115 disposed on the second side 101b, where each of the plurality of second conductive structures 115 is electrically connected to one corresponding fourth conductive plug 114 among the plurality of fourth conductive plugs 114.

In the embodiment, a material of the first epitaxial layer 108 and the second epitaxial layers 106 includes gallium nitride.

Accordingly, an embodiment of the present disclosure further provides an automobile lamp. Still referring to FIG. 14, the automobile lamp includes the Micro LED chip as described in any one of the above embodiments. A traditional automobile lamp is replaced with the Micro LED chip, which may effectively improve a resolution and luminous flux of the automobile lamp.

Although the present disclosure has been disclosed above with reference to the embodiments thereof, it should be understood that the disclosure is presented by way of example only, and not limitation. Therefore, the scope of the present disclosure shall be subject to the scope defined by the claims.

What is claimed is:

1. A Micro-Light Emitting Diode (Micro LED) chip, comprising:
a first epitaxial layer, wherein the first epitaxial layer has first doping ions therein, and has a first side and a second side opposite to each other;
a plurality of multi-quantum well layers disposed on the first side and in contact with the first epitaxial layer;
a plurality of second epitaxial layers disposed on the first side, wherein the plurality of second epitaxial layers have second doping ions therein, the second doping ions and the first doping ions are of different electrical types, and each of the plurality of multi-quantum well layers is disposed between the first epitaxial layer and one corresponding second epitaxial layer among the plurality of second epitaxial layers; and
a plurality of conductive mirror layers disposed on the first side, wherein each of the plurality of conductive mirror layers is electrically connected to one corresponding second epitaxial layer among the plurality of second epitaxial layers, and surrounds a non-light-emitting side of one corresponding multi-quantum well layer among the plurality of multi-quantum well layers.

2. The Micro LED chip according to claim 1, further comprising: a plurality of micro-lenses disposed on the second side,
wherein a light-emitting side of each of the plurality of multi-quantum well layers faces one corresponding micro-lens among the plurality of micro-lenses, and a projection area of each of the plurality of multi-quantum well layers toward the corresponding second epitaxial layer is disposed within a projection area range of the corresponding micro-lens toward the corresponding second epitaxial layer.

3. The Micro LED chip according to claim 2, further comprising: a plurality of fluorescent layers disposed on the second side,
wherein each of the plurality of fluorescent layers is disposed between one corresponding multi-quantum well layer among the plurality of multi-quantum well layers and one corresponding micro-lens among the plurality of micro-lenses, and the plurality of fluorescent layers are configured to adjust a color of light emitted by the plurality of multi-quantum well layers toward the micro-lenses.

4. The Micro LED chip according to claim 3, wherein the plurality of fluorescent layers excite light of a first wavelength, and the light of the first wavelength is displayed as a first color light; the plurality of multi-quantum well layers excite light of a second wavelength, and the light of the second wavelength is displayed as a second color light; the first wavelength is different from the second wavelength; and the first color light and the second color light are mixed into a third color light; or
wherein the Micro LED chip further comprises a dam structure disposed on the second side, wherein the dam structure comprises a plurality of first through holes each of which exposes a light emission path of one corresponding multi-quantum well layer among the plurality of multi-quantum well layers, and each of the plurality of fluorescent layers is filled in one corresponding first through hole among the plurality of first through holes.

5. The Micro LED chip according to claim 4, further comprising: a first conductive structure disposed on the second side,
wherein the first conductive structure is electrically connected to the first epitaxial layer, and disposed between the dam structure and the first epitaxial layer, the first conductive structure comprises a plurality of second through holes, and each of the plurality of first through holes exposes one corresponding second through hole among the plurality of second through holes.

6. The Micro LED chip according to claim 5, wherein each of the plurality of fluorescent layers is also filled in the corresponding second through hole; or
wherein the Micro LED chip further comprises a second ohmic contact layer disposed on the second side, wherein the second ohmic contact layer is disposed between the first conductive structure and the first epitaxial layer.

7. The Micro LED chip according to claim 1, wherein the Micro LED chip further comprises a plurality of first ohmic contact layers disposed on the first side, wherein each of the plurality of first ohmic contact layers is disposed between one corresponding conductive mirror layer among the plurality of conductive mirror layers and one corresponding second epitaxial layer among the plurality of second epitaxial layers; or
wherein the Micro LED chip further comprises: a plurality of first conductive plugs disposed on the first side, wherein each of the plurality of first conductive plugs is electrically connected to one corresponding second epitaxial layer among the plurality of second epitaxial layers; and a driving backplane comprising a driving circuit layer, wherein the plurality of first conductive plugs are electrically connected to the driving circuit layer.

8. The Micro LED chip according to claim 7, wherein the driving backplane further comprises a plurality of driving backplane conductive plugs electrically connected to the driving circuit layer, and the plurality of first conductive plugs are electrically connected to the driving circuit layer respectively through the plurality of driving backplane conductive plugs.

9. The Micro LED chip according to claim 8, wherein the Micro LED chip further comprises a bonding layer disposed between the driving backplane and the plurality of first conductive plugs, wherein the bonding layer comprises a plurality of second conductive plugs and a plurality of metal plates, each of the plurality of metal plates is electrically connected to several of the plurality of driving backplane conductive plugs, each of the plurality of second conductive plugs is electrically connected to one corresponding metal plate among the plurality of metal plates, and each of the plurality of first conductive plugs is electrically connected to one corresponding second conductive plug among the plurality of second conductive plugs;
wherein the driving backplane further comprises a plurality of functional conductive plugs electrically connected to the driving circuit layer, and the bonding layer further comprises a plurality of third conductive plugs each of which is electrically connected to one corresponding functional conductive plug among the plurality of functional conductive plugs; and
wherein the Micro LED chip further comprises: a plurality of fourth conductive plugs disposed on the first side, wherein each of the plurality of fourth conductive plugs is electrically connected to one corresponding third conductive plug among the plurality of third conductive plugs; and a plurality of second conductive structures disposed on the second side, wherein each of the plurality of second conductive structures is electrically connected to one corresponding fourth conductive plug among the plurality of fourth conductive plugs.

10. A method for forming a Micro-Light Emitting Diode (Micro LED) chip, comprising:
forming a first epitaxial layer, having first doping ions therein and having a first side and a second side opposite to each other;
forming a plurality of multi-quantum well layers on the first side and in contact with the first epitaxial layer;
forming a plurality of second epitaxial layers on the first side, wherein the plurality of second epitaxial layers have second doping ions therein, the second doping ions and the first doping ions are of different electrical types, and each of the plurality of multi-quantum well layers is disposed between the first epitaxial layer and one corresponding second epitaxial layer among the plurality of second epitaxial layers; and
forming a plurality of conductive mirror layers on the first side, wherein each of the plurality of conductive mirror layers is electrically connected to one corresponding second epitaxial layer among the plurality of second epitaxial layers, and surrounds a non-light-emitting side of one corresponding multi-quantum well layer among the plurality of multi-quantum well layers.

11. The method according to claim 10, wherein prior to said forming the plurality of conductive mirror layers, the method further comprises:
forming a plurality of first ohmic contact layers on the first side, wherein each of the plurality of first ohmic contact layers is disposed between one corresponding conductive mirror layer among the plurality of conductive mirror layers and the corresponding second epitaxial layer.

12. The method according to claim 11, wherein said forming the first epitaxial layer, the plurality of first ohmic contact layers, the plurality of second epitaxial layers and the plurality of multi-quantum well layers comprises:
providing a temporary substrate;
forming a first epitaxial material layer on the temporary substrate;
forming a multi-quantum well material layer on the first epitaxial material layer;
forming a second epitaxial material layer on the multi-quantum well material layer;
forming a first ohmic contact material layer on the second epitaxial material layer; and
performing patterned etching on the first ohmic contact material layer, the second epitaxial material layer, the multi-quantum well material layer and the first epitaxial material layer to form the plurality of first ohmic contact layers, the plurality of second epitaxial layers, the plurality of multi-quantum well layers and the first epitaxial layer.

13. The method according to claim 10, wherein said forming the plurality of conductive mirror layers comprises: forming a third photoresist structure on the first side; forming a mirror material layer on the first side, wherein the mirror material layer covers the third photoresist structure; and removing the third photoresist structure and the mirror material layer on the third photoresist structure to form the plurality of conductive mirror layers; or
wherein following said forming the plurality of conductive mirror layers, the method further comprises: forming a plurality of first conductive plugs on the first side, wherein each of the plurality of first conductive plugs is electrically connected to one corresponding second epitaxial layer among the plurality of second epitaxial layers; and
providing a driving backplane comprising a driving circuit layer, wherein the plurality of first conductive plugs are electrically connected to the driving circuit layer; or
wherein following said forming the conductive mirror layer, the method further comprises: forming a plurality of micro-lenses on the second side, wherein a light-emitting side of each of the plurality of multi-quantum well layers faces one corresponding micro-lens among the plurality of micro-lenses, and a projection area of each of the plurality of multi-quantum well layers toward the corresponding second epitaxial layer is disposed within a projection area range of the corresponding micro-lens toward the corresponding second epitaxial layer.

14. The method according to claim 13, wherein the driving backplane further comprises a plurality of driving backplane conductive plugs electrically connected to the driving circuit layer, and the plurality of first conductive plugs are electrically connected to the driving circuit layer respectively through the plurality of driving backplane conductive plugs.

15. The method according to claim 14, wherein following said providing the driving backplane, the method further comprises: forming a bonding layer on the driving backplane, wherein the bonding layer comprises a plurality of second conductive plugs and a plurality of metal plates, each of the plurality of metal plates is electrically connected to several of the plurality of driving backplane conductive plugs, and each of the plurality of second conductive plugs is electrically connected to one corresponding metal plate among the plurality of metal plates; and bonding each of the plurality of first conductive plugs to one corresponding second conductive plug among the plurality of second conductive plugs;
wherein the driving backplane further comprises a plurality of functional conductive plugs electrically connected to the driving circuit layer, and the bonding layer further comprises a plurality of third conductive plugs each of which is electrically connected to one corresponding functional conductive plug among the plurality of functional conductive plugs; and
wherein the method further comprises: forming a plurality of fourth conductive plugs on the first side, wherein each of the plurality of fourth conductive plugs is electrically connected to one corresponding third conductive plug among the plurality of third conductive plugs; and forming a plurality of second conductive structures disposed on the second side, wherein each of the plurality of second conductive structures is electrically connected to one corresponding fourth conductive plug among the plurality of fourth conductive plugs.

16. The method according to claim 13, wherein prior to said forming the plurality of micro-lenses, the method further comprises:
forming a plurality of fluorescent layers on the second side, wherein each of the plurality of fluorescent layers is disposed between one corresponding multi-quantum well layer among the plurality of multi-quantum well layers and one corresponding micro-lens among the plurality of micro-lenses, and the plurality of fluorescent layers are configured to adjust a color of light emitted by the plurality of multi-quantum well layers toward the micro-lenses.

17. The method according to claim 16, wherein prior to said forming the plurality of fluorescent layers, the method further comprises:
forming a dam structure on the second side, wherein the dam structure comprises a plurality of first through holes each of which exposes a light emission path of one corresponding multi-quantum well layer among the plurality of multi-quantum well layers, and each of the plurality of fluorescent layers is filled in one corresponding first through hole among the plurality of first through holes.

18. The method according to claim 17, wherein said forming the dam structure comprises:
forming a plurality of first photoresist structures on the second side, with a first gap between adjacent first photoresist structures; forming the dam structure in the first gap; and removing the plurality of first photoresist structures after forming the dam structure, to make the dam structure have the plurality of first through holes; or
wherein prior to said forming the dam structure, the method further comprises: forming a first conductive structure on the second side, wherein the first conductive structure is electrically connected to the first epitaxial layer, and disposed between the dam structure and the first epitaxial layer, the first conductive structure comprises a plurality of second through holes, and each of the plurality of first through holes exposes one corresponding second through hole among the plurality of second through holes.

19. The method according to claim 18, wherein said forming the first conductive structure comprises: forming a plurality of second photoresist structures on the second side, with a second gap between adjacent second photoresist structures; forming the first conductive structure in the second gap; removing the plurality of second photoresist structures after forming the first conductive structure, to make the first conductive structure have the plurality of second through holes; or
wherein each of the plurality of fluorescent layers is also filled in the corresponding second through hole; or
wherein prior to said forming the first conductive structure, the method further comprises: forming a second ohmic contact layer on the second side, wherein the second ohmic contact layer is disposed between the first conductive structure and the first epitaxial layer.

20. An automobile lamp, comprising a Micro-Light Emitting Diode (Micro LED) chip, wherein the Micro LED chip comprises:
a first epitaxial layer, wherein the first epitaxial layer has first doping ions therein, and has a first side and a second side opposite to each other;
a plurality of multi-quantum well layers disposed on the first side and in contact with the first epitaxial layer;
a plurality of second epitaxial layers disposed on the first side, wherein the plurality of second epitaxial layers have second doping ions therein, the second doping ions and the first doping ions are of different electrical types, and each of the plurality of multi-quantum well layers is disposed between the first epitaxial layer and one corresponding second epitaxial layer among the plurality of second epitaxial layers; and
a plurality of conductive mirror layers disposed on the first side, wherein each of the plurality of conductive mirror layers is electrically connected to one corresponding second epitaxial layer among the plurality of second epitaxial layers, and surrounds a non-light-emitting side of one corresponding multi-quantum well layer among the plurality of multi-quantum well layers.
